(19) United States
(12) Patent Application Publication
(10) Pub. No.: US 2016/0336971 A1
(43) Pub. Date: Nov. 17, 2016

(54) CONSENSUS DECODING ALGORITHM FOR GENERALIZED REED-SOLOMON CODES

(71) Applicant: U.S.A. represented by the Administrator of the National Aeronautics and Space Administration, Washington, DC (US)

(72) Inventors: WAI FONG, (US); WING LEE, (US)

(21) Appl. No.: 14/712,027

(22) Filed: May 14, 2015

(51) Int. Cl. H03M 13/00; H03M 13/15

(52) U.S. Cl. CPC H03M 13/616; H03M 13/1515

(57) ABSTRACT

Disclosed are systems, methods and computer-readable media for providing a consensus decoding algorithm for a generalized Reed-Solomon Code. The method includes calculating a syndrome on a received data pattern using a unique subspace parity-check matrix inside each of a plurality of consensus decoders, generating respective extrinsic information from each check node to variable node in each consensus decoder of the plurality of consensus decoders to yield complete extrinsic information, performing a unanimous vote on the complete extrinsic information to determine an error estimate for each variable node in each consensus decoder, combining error estimates for each variable node generated from the plurality of consensus decoders to yield a final error estimate and correcting the received data pattern according to the final error estimate.

### BACKGROUND

1. Technical Field

The present disclosure relates to a highly parallelized decoding algorithm, named Consensus Decoding Algorithm (CDA), which can be used to decode Generalized Reed-Solomon (GRS) error correction codes.

2. Introduction

Ensuring reliability and correctness of the data stored in memory devices is paramount to the success of many communication systems including every space flight mission at NASA. Currently, onboard memory storage devices suffer from radiation effects that can induce single event effects (SEEs) causing temporary or permanent damage to the devices. One method for mitigating the radiation effects is to provide error detection and correction (EDAC) capability to memory accesses. By appending controlled redundancy to every memory word, mathematically based decoding algorithms can correct errors, thereby providing secure and reliable memory for programs and data storage. In previous space missions, the command and data-handling units employed a Reed-Solomon (RS) EDAC as the main error mitigation technique. This EDAC utilizes the most common Berlekamp Massey (BM) decoding algorithm that involves solving a set of nonlinear equations in an iterative manner during its decoding process and thereby can result in multiple clock cycles of latency and limit the access rate. To minimize decoding latency and increase the memory access bandwidth, the present inventors initiated a study to improve this performance specification. As a result of the study, a highly parallelized decoding algorithm, named Consensus Decoding Algorithm (CDA), was introduced to decode GRS codes, a superset of RS codes.

### SUMMARY

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. The features of the disclosure will become more fully apparent from the following description and appended claims, or can be learned by the practice of the principles set forth herein.

During the study referenced above, the Consensus Decoding Algorithm (CDA) was developed to decode a superset family of non-binary maximum distance separable (MDS) codes based on Reed-Solomon, known as generalized Reed-Solomon (GRS) codes. The CDA uses a parallelized construction of a set of a priori generated subspace parity-check matrices for decoding. Unlike typical decoding algorithms used for RS code, i.e. Berlekamp Massey (BM), whose implementation results in multiple clock cycles of latency, the decoding procedure disclosed herein is highly parallelized and can be completed within a single clock cycle.

The practical limitation of the decoding algorithm is constrained by the extra hardware resources it requires from the parallelization. The inventors suggest limiting the code to correct up to two symbol errors for short block codes that are less than 100 bits. Therefore, a target application is any memory storage system that requires one to two symbol error correction for its data storage and have a data access bus with size (assume same as length of codeword) less than the length specified above. As technology evolves and field programmable gate array (FPGA) devices contain higher capacity, the code can certainly be extended for larger error correction and larger codeword sizes.

An example method embodiment of the disclosure includes illustrations of the decoding process to correct for potential channel corrupted GRS codewords, wherein the method includes processing each received GRS code with a set of a priori generated subspace parity-check matrices at the decoder. The final result is a combination of the output of all subspace decoders.

The more detailed steps in the decoding process involve calculating the syndrome on a received data pattern using a unique subspace parity-check matrix inside each of a plurality of consensus decoders, generating respective extrinsic information from each check node to variable node in each consensus decoder to yield complete extrinsic information, and performing a unanimous vote on the complete extrinsic information to determine an error estimate for each variable node in each consensus decoder. The steps also include combining error estimates for each variable node generated from the plurality of consensus decoders to yield a final error estimate and correcting the received data pattern according to the final error estimate.

### BRIEF DESCRIPTION OF THE DRAWINGS

FIG. 1A illustrates an example system embodiment;

FIG. 1B illustrates use of the EDAC;

FIG. 2A illustrates a general structure of consensus decoding;

FIG. 2B illustrates a consensus decoding block diagram for an example (10,8) code;

FIG. 2C illustrates a consensus decoding block diagram for an example (6,2) code;

FIG. 3 illustrates the message passing directions to V-node 1 in a consensus decoder;

FIG. 4 illustrates an example EDAC core interface;

FIG. 5 illustrates the EDAC setup for performance testing; and

FIG. 6 illustrates a method embodiment for Consensus decoding process.

### DETAILED DESCRIPTION

Various embodiments of the disclosure are described in detail below. While specific implementations are described, it should be understood that the description is done for illustration purposes only. Other components and configurations may be used without parting from the spirit and scope of the disclosure.

The disclosure addresses generally a method of decoding Generalized Reed-Solomon (GRS) codes. The method includes processing each received GRS code with a set of a priori generated subspace parity-check matrices at the decoder, applying the Consensus Decoding Algorithm to yield results and determining an error correction action to the received codeword according to the results.

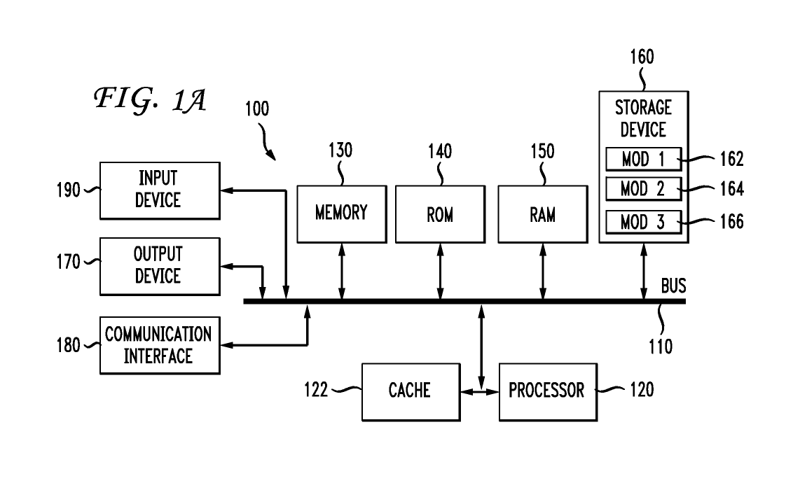

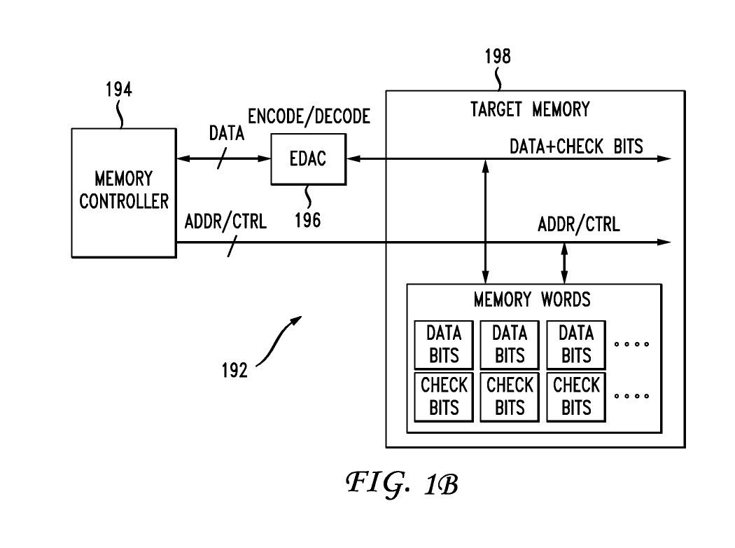

Prior to continuing with a discussion of the particular features of the disclosure, the disclosure first turns to FIG. 1A and a description of computer hardware for use in applying the concepts disclosed herein.

With reference to FIG. 1A, an exemplary system and/or computing device 100 includes a processing unit (CPU or processor) 120 and a system bus 110 that couples various system components including the system memory 130 such as read only memory (ROM) 140 and random access memory (RAM) 150 to the processor 120. The system 100 can include a cache 122 of high-speed memory connected directly with, in close proximity to, or integrated as part of the processor 120. The system 100 copies data from the memory 130 and/or the storage device 160 to the cache 122 for quick access by the processor 120. The cache provides a performance boost that avoids processor 120 delays while waiting for data. The modules and other modules can control or be configured to control the processor 120 to perform various operations or actions. Other system memory 130 may be available for use as well. The memory 130 can include multiple different types of memory with different performance characteristics. It can be appreciated that the disclosure may operate on a computing device 100 with more than one processor 120 or on a group or cluster of computing devices networked together to provide greater processing capability. The processor 120 can include any general purpose processor and a hardware module or software module, such as module 1 162, module 2 164, and module 3 166 stored in storage device 160, configured to control the processor 120 as well as a special-purpose processor where software instructions are incorporated into the processor. The processor 120 may be a self-contained computing system, containing multiple cores or processors, a bus, memory controller, cache, etc. A multi-core processor may be symmetric or asymmetric. The processor 120 can include multiple processors, such as a system having multiple, physically separate processors in different sockets, or a system having multiple processor cores on a single physical chip. Similarly, the processor 120 can include multiple distributed processors located in multiple separate computing devices, but working together such as via a communications network. Multiple processors or processor cores can share resources such as memory 130 or the cache 122, or can operate using independent resources. The processor 120 can include one or more of a state machine, an application specific integrated circuit (ASIC), or a programmable gate array (PGA) including a field PGA.

The system bus 110 may be any of several types of bus structures including a memory bus or memory controller, a peripheral bus, and a local bus using any of a variety of bus architectures. A basic input/output (BIOS) stored in ROM 140 or the like, may provide the basic routine that helps to transfer information between elements within the computing device 100, such as during start-up. The computing device 100 further includes storage devices 160 or computer-readable storage media such as a hard disk drive, a magnetic disk drive, an optical disk drive, tape drive, solid-state drive, RAM drive, removable storage devices, a redundant array of inexpensive disks (RAID), hybrid storage device, or the like. The storage device 160 can include software modules 162, 164, 166 for controlling the processor 120. The system 100 can include other hardware or software modules. The storage device 160 is connected to the system bus 110 by a drive interface. The drives and the associated computer-readable storage devices provide nonvolatile storage of computer-readable instructions, data structures, program modules and other data for the computing device 100. In one aspect, a hardware module that performs a particular function includes the software component stored in a tangible computer-readable storage device in connection with the necessary hardware components, such as the processor 120, bus 110, display 170, and so forth, to carry out a particular function. In another aspect, the system can use a processor and computer-readable storage device to store instructions which, when executed by the processor, cause the processor to perform operations, a method or other specific actions. The basic components and appropriate variations can be modified depending on the type of device, such as whether the device 100 is a small, handheld computing device, a desktop computer, or a computer server. When the processor 120 executes instructions to perform “operations”, the processor 120 can perform the operations directly and/or facilitate, direct, or cooperate with another device or component to perform the operations.

Although the exemplary embodiment(s) described herein employs the hard disk 160, other types of computer-readable storage devices which can store data that are accessible by a computer, such as magnetic cassettes, flash memory cards, digital versatile disks (DVDs), cartridges, random access memories (RAMs) 150, read only memory (ROM) 140, a cable containing a bit stream and the like, may also be used in the exemplary operating environment. Tangible computer-readable storage media, computer-readable storage devices, or computer-readable memory devices, expressly exclude media such as transitory waves, energy, carrier signals, electromagnetic waves, and signals per se.

To enable user interaction with the computing device 100, an input device 190 represents any number of input mechanisms, such as a microphone for speech, a touch-sensitive screen for gesture or graphical input, keyboard, mouse, motion input, speech and so forth. An output device 170 can also be one or more of a number of output mechanisms known to those of skill in the art. In some instances, multimodal systems enable a user to provide multiple types of input to communicate with the computing device 100. The communications interface 180 generally governs and manages the user input and system output. There is no restriction on operating on any particular hardware arrangement and therefore the basic hardware depicted may easily be substituted for improved hardware or firmware arrangements as they are developed.

For clarity of explanation, the illustrative system embodiment is presented as including individual functional blocks including functional blocks labeled as a “processor” or processor 120. The functions the blocks represent may be provided through the use of either shared or dedicated hardware, including, but not limited to, hardware capable of executing software and hardware, such as a processor 120, that is purpose-built to operate as an equivalent to software executing on a general purpose processor. For example the functions of one or more processors presented in FIG. 1A may be provided by a single shared processor or multiple processors. (Use of the term “processor” should not be construed to refer exclusively to hardware capable of executing software.) Illustrative embodiments may include microprocessor and/or digital signal processor (DSP) hardware, read-only memory (ROM) 140 for storing software performing the operations described below, and random access memory (RAM) 150 for storing results. Very large scale integration (VLSI) hardware embodiments, as well as custom VLSI circuitry in combination with a general purpose DSP circuit, may also be provided.

The logical operations of the various embodiments are implemented as: (1) a sequence of computer implemented steps, operations, or procedures running on a programmable circuit within a general use computer, (2) a sequence of computer implemented steps, operations, or procedures running on a specific-use programmable circuit; and/or (3) interconnected machine modules or program engines within the programmable circuits. The system 100 shown in FIG. 1A can practice all or part of the recited methods, can be a part of the recited systems, and/or can operate according to instructions in the recited tangible computer-readable storage devices. Such logical operations can be implemented as modules configured to control the processor 120 to perform particular functions according to the programming of the module. For example, FIG. 1A illustrates three modules Mod1 162, Mod2 164 and Mod3 166 which are modules configured to control the processor 120. The modules may be stored on the storage device 160 and loaded into RAM 150 or memory 130 at runtime or may be stored in other computer-readable memory locations.

One or more parts of the example computing device 100, up to and including the entire computing device 100, can be virtualized. For example, a virtual processor can be a software object that executes according to a particular instruction set, even when a physical processor of the same type as the virtual processor is unavailable. A virtualization layer or a virtual “host” can enable virtualized components of one or more different computing devices or device types by translating virtualized operations to actual operations. Ultimately however, virtualized hardware of every type is implemented or executed by some underlying physical hardware. Thus, a virtualization compute layer can operate on top of a physical compute layer. The virtualization compute layer can include one or more of a virtual machine, an overlay network, a hypervisor, virtual switching, and any other virtualization application.

The processor 120 can include all types of processors disclosed herein, including a virtual processor. However, when referring to a virtual processor, the processor 120 includes the software components associated with executing the virtual processor in a virtualization layer and underlying hardware necessary to execute the virtualization layer. The system 100 can include a physical or virtual processor 120 that receive instructions stored in a computer-readable storage device, which cause the processor 120 to perform certain operations. When referring to a virtual processor 120, the system also includes the underlying physical hardware executing the virtual processor 120.

FIG. 1B illustrates 192 how EDACs 196 are being used to protect onboard memory 198. The figure shows the interface between the EDAC core 196, a memory controller 194 and a memory module 198. To mitigate errors due to radiation effects, the EDAC 196 needs to access each memory word and periodically scans through the entire memory 198 to detect any corrupted bits. These corrupted bits are detected by using parity-checks attached to the codeword. Corrupted data can then be corrected and written back to those affected memory words. The process of detecting and correcting memory bit errors is known as scrubbing. Besides periodic memory scrubbing, the EDAC 196 also performs encoding and decoding during write and read operations to ensure the correctness of data.

The principles disclosed herein are more understandable with a fundamental knowledge of coding theory, which is presumed by the reader of this application. Therefore, only a brief description of the Generalized Reed-Solomon (GRS) code is provided below.

The Generalized Reed-Solomon (GRS) code is a family of non-binary maximum distance separable (MDS) codes. They can provide the highest guaranteed error detection and correction capability at a given code rate comparing to non-MDS codes. By appending 2t parity symbols to the information, the GRS code can detect up to 2t erroneous symbols, or correct up to t symbols. Its maximum codeword length is limited by the Galois field (GF) of the code as in RS, and the code dimensions must satisfy the equation that N is less than or equal to (q−1) and K=N−2t, where,
N is the total number of symbols in a codeword,
K is the number of information symbols in a codeword,
q is the number of elements in the Galois field of the non-binary code, and
t is the error correction capability of the code.
   The above conventional notations will be used repeatedly throughout this disclosure.

Having discussed the fundamentals of Generalized Reed-Solomon (GRS) code above, the disclosure turns to the development of the Consensus Decoding Algorithm (CDA) for decoding these GRS codes. The first part of the disclosure describes the specific construction to generate the set of subspace parity-check matrices required by the CDA. The next part of the disclosure provides the CDA decoding process in great detail.

First, a method of constructing the parity-check matrix of a GRS code, denoted as H, is discussed. Let z be a generator vector for the parity-check matrix and x be a Vandermonde generator vector, defined as:

z [symbol] (z₁, z₂, . . . , z_{N}),

x [symbol] (x₁, x₂, . . . , x_{N}),

where each zⱼ and xⱼ can be any random non-zero element in GF(q), and specifically for xⱼ, the selected elements are required to be unique within the set that includes all xⱼ. Let xⁱ=(x₁ⁱ, x₂ⁱ, . . . , x_{N}ⁱ), then, the parity-check matrix H of the code can be constructed through the equation below:

$$H = {[ \begin{matrix}z ∘ {x}^{0} \\ z ∘ {x}^{1} \\ z ∘ {x}^{2} \\ ⋮ \\ z ∘ {x}^{N - K - 1}\end{matrix} ]}_{( N - K ) \times N} ,$$

where o denotes the Hadamard product. And each element in H can be written as:

h_{i,j}=zⱼ*xⱼⁱ⁻¹,

for 1≦i≦N−K and 1≦j≦N.

Two examples are shown below to illustrate how H is constructed. For both examples assume N=6, K=2 and q=8. Here's the first example, let:

$$z = ( {α}^{2} , {α}^{0} , {α}^{2} , {α}^{1} , {α}^{6} , {α}^{4} ) , \\ x = ( {α}^{4} , {α}^{6} , {α}^{3} , {α}^{0} , {α}^{1} , {α}^{5} ) , \\ H = [ \begin{matrix}{α}^{2} & {α}^{0} & {α}^{2} & {α}^{1} & {α}^{6} & {α}^{4} \\ {α}^{6} & {α}^{6} & {α}^{5} & {α}^{1} & {α}^{0} & {α}^{2} \\ {α}^{3} & {α}^{5} & {α}^{1} & {α}^{1} & {α}^{1} & {α}^{0} \\ {α}^{0} & {α}^{4} & {α}^{4} & {α}^{1} & {α}^{2} & {α}^{5}\end{matrix} ] .$$

Here is another example. Let:

$$z = x = ( {α}^{0} , {α}^{1} , {α}^{2} , {α}^{3} , {α}^{4} , {α}^{5} ) , \\ H = [ \begin{matrix}{α}^{0} & {α}^{1} & {α}^{2} & {α}^{3} & {α}^{4} & {α}^{5} \\ {α}^{0} & {α}^{2} & {α}^{4} & {α}^{6} & {α}^{1} & {α}^{3} \\ {α}^{0} & {α}^{3} & {α}^{6} & {α}^{2} & {α}^{5} & {α}^{1} \\ {α}^{0} & {α}^{4} & {α}^{1} & {α}^{5} & {α}^{2} & {α}^{6}\end{matrix} ] .$$

Notice that the 2nd example results in a parity-check matrix identical to a shortened (6, 2) Reed-Solomon code. The GRS code includes the RS code as a subset because the codes are both developed based on Vandermonde matrices.

Having described a way of constructing the parity-check matrix of GRS codes, the generation of the set of subspace parity-check matrices are described herein. With these subspace matrices determined a priori using the original H matrix discussed earlier, the Consensus Decoding Algorithm can process each received GRS code with the subspace parity-check matrices alone. In other words, the original H matrix is not required in the real time decoding process. Next is explained how subspace H matrices are generated. Let's first denote each of the

$$( \begin{matrix}N \\ t - 1\end{matrix} )$$

subspace matrices by Hₚ^{(A}^{ⱼ}⁾, where Aⱼ represents any t−1 element subset of N columns that are being punctured in H and

$$0 < j \leq ( \begin{matrix}N \\ t - 1\end{matrix} ) .$$

The set that includes all Aᵢ is denoted by A and so there are a total of

$$( \begin{matrix}N \\ t - 1\end{matrix} )$$

combinations or subsets in A. The term A is defined formally as:
A={Aⱼ|Aⱼ={a₁, a₂, . . . , aₜ₋₁ΛAⱼ consists of unique elements from

$$\{ 1 , 2 , … , N \} 0 < j \leq ( \begin{matrix}N \\ t - 1\end{matrix} ) \} .$$

where ̂ denotes the logical AND operation.

For example, with N=7 and t=2, the following matrices are generated:
Hₚ⁽¹⁾, Hₚ⁽²⁾, Hₚ⁽³⁾, . . . , Hₚ⁽⁷⁾, . For N=7 and t=3, the following apply: Hₚ^{(1,2)}, Hₚ^{(1,3)}, Hₚ^{(1,4)}, Hₚ^{(1,5)}, Hₚ^{(1,6)}, Hₚ^{(1,7)}, Hₚ^{(2,3)}, Hₚ^{(2,4)}, Hₚ^{(2,5)}, Hₚ^{(2,6)}, Hₚ^{(2,7)}, Hₚ^{(3,4)}, Hₚ^{(3,5)}, Hₚ^{(3,6)}, Hₚ^{(3,7)}, Hₚ^{(4,5)}, Hₚ^{(4,6)}, Hₚ^{(4,7)}, Hₚ^{(5,6)}, Hₚ^{(5,7)} and Hₚ^{(6,7)}. For t=1, Aⱼ is an empty set and Hₚ=H.
   The elements in each Hₚ^{(A}^{ⱼ}⁾ subspace matrix can be generated using the equation below:

h_{P}_{_{i,j}}^{(A}^{ⱼ}⁾=Hₖ₌₁^{t+1}(xₐ_{ₖ}+xⱼ)·h_{i,j},

where 1≦i≦t+1 and 1≦j≦N. And each matrix should have the form:

$${H}_{P}^{( {A}_{j} )} = {[ \begin{matrix}{h}_{{P}_{1 , 1}} & {h}_{{P}_{1 , 2}} & … & {h}_{{P}_{1 , N}} \\ {h}_{{P}_{2 , 1}} & {h}_{{P}_{2 , 2}} & … & {h}_{{P}_{2 , N}} \\ ⋮ & ⋮ & ⋮ & ⋮ \\ {h}_{{P}_{( t + 1 ) , 1}} & {h}_{{P}_{( t + 1 ) , 2}} & … & {h}_{{P}_{( t + 1 ) , N}}\end{matrix} ]}_{( t + 1 ) \times N} ,$$

where the columns Aⱼ={a₁, a₂, . . . , aₜ₋₁} should be zero. Using the example provided earlier for a code with N=7 and t=3, h_{P}_{_{i,j}}^{(1,3)}=(x₁+xⱼ)(x₃+xⱼ)h_{i,j} and h_{P}_{_{i,j}}^{(2,7)}=(x₂+xⱼ)(x₇+xⱼ)h_{i,j}).

We have at this point defined the construction of the

$$( \begin{matrix}N \\ t - 1\end{matrix} )$$

subspace parity-check matrices of the GRS code. The idea behind this construction to isolate each erred symbol in the received pattern by nullifying the effect of additional errors from all other possible combinations of error locations. When the number of erred symbols are within the error correction capability, t, of the code, then decoding using all Hₚ matrices can effectively isolate each error so that consensus decoding (CD) can be performed by solving the parity-check equations to correct for each error separately. Next, the general algorithm for consensus decoding is described and we shall see how these subspace parity-check matrices are used in the decoding process.

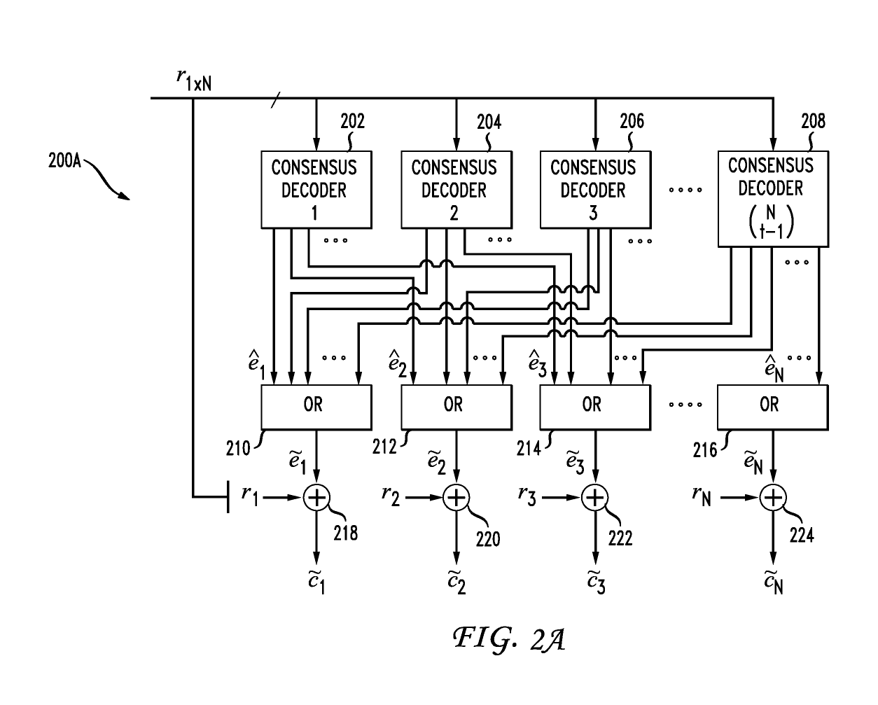

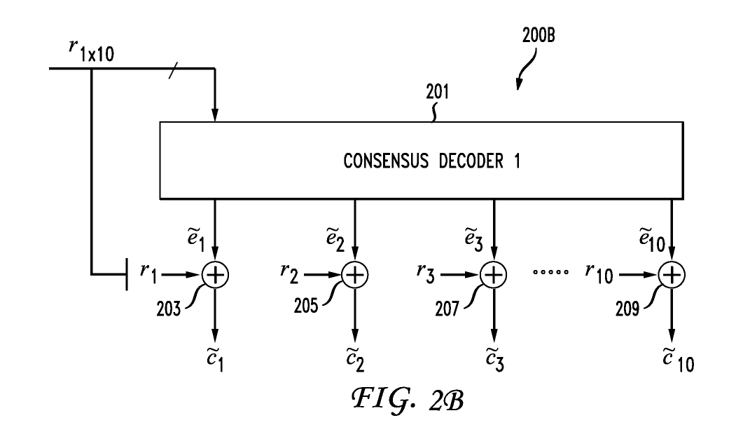

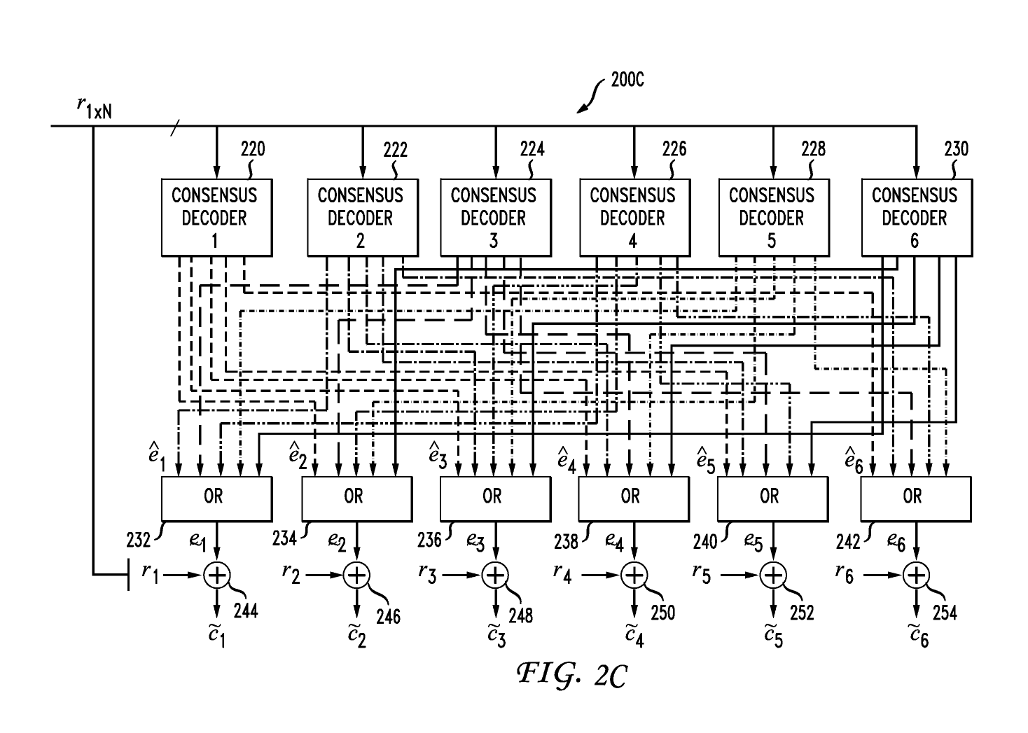

FIG. 2A illustrates the top level decoding process 200A of the CDA. Using the

$$( \begin{matrix}N \\ t - 1\end{matrix} )$$

submatrices of the original parity-check matrix, consensus decoding (CD) is performed to the received vector r. What is meant by the CD is that a decision on the value of a received symbol is made by unanimous vote of all the available information in regards to that symbol. Alternately, the vote does not have to be unanimous. Note that there are

$$( \begin{matrix}N \\ t - 1\end{matrix} )$$

consensus decoders (CDR)s in the diagram and each uses a unique subspace parity-check matrix Hₚ^{(k)} that are described previously. The number of consensus decoders can also be determined to be N representing any plurality of consensus decoders. The superscript k represents the Hp used in consensus decoder k. Each one of the consensus decoders (CDRs) 202, 204, 206, 208 generates and outputs its own estimate of the error vector ê and all estimates associated with each symbol location are combined together through the OR'ing process 210, 212, 214, 216. The final error estimate vector, \tilde{e}, is then added, or XOR'ed, to the received symbols 218, 220, 222, 224 to provide an estimation of the codeword. The system may include N−2 other consensus decoders each producing an estimate of the error associated with each received symbol location.

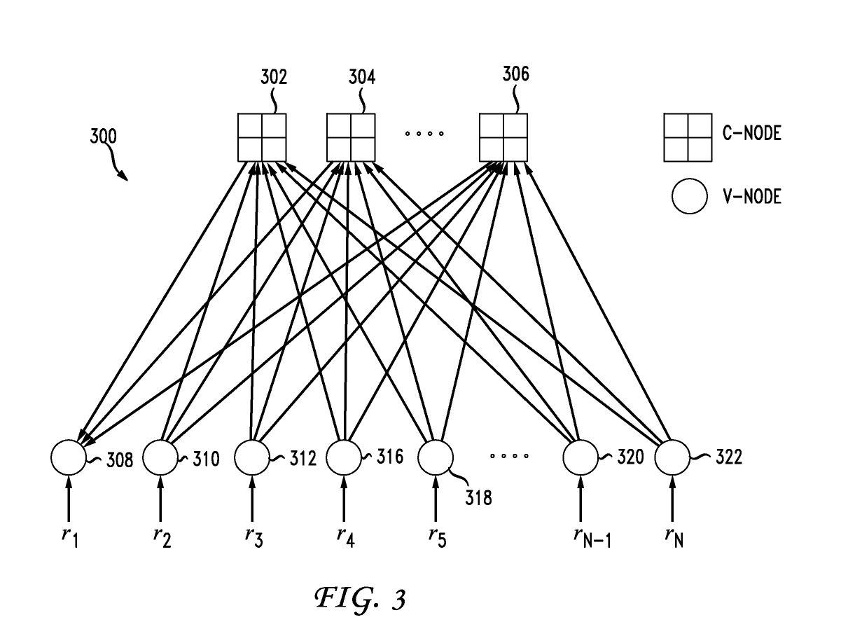

To explain the detail signal processing within a CDR, the concept of “message passing” needs to be first stated. A message passing decoder is generally considered a decoder based on two classes of processors or nodes, i.e. variable (V-node) and check (C-node). The decoding process can be visualized with a Tanner graph (bi-partite), as shown in FIG. 3. The Tanner graph 300 is a simple graphical way of representing a parity-check matrix H, of an error correction code. In the graph 300, the C-nodes 302, 304, 306 represent the rows and V-nodes 308, 310, 312, 316, 318, 320, 322 represent the columns of the H matrix. The connections between the nodes are defined as the non-zero elements in the H matrix.

In a message passing decoder, information from the channel is transferred from V-nodes to C-nodes and back to complete a decoding step. The message transfer is performed in parallel among all nodes and therefore achieves very high data rates. The process begins at the V-nodes where the channel information is sent to all connected check nodes in parallel. Since each check node represents a parity-check equation, a C-node sends back information to the V-node along a connection by excluding (or subtracting) its own information from that parity-check equation. The resultant information is called “extrinsic”. As an example, FIG. 3 shows an example structure 300 illustrating the extrinsic information going back to V-node 1 308. As the last step, a decision is made at each V-node using the extrinsic information. There are many well-known decoders that use the message passing mechanism. Two examples are the bit flipping decoder and the sum-product algorithm (SPA) decoder for low-density parity-check (LDPC) codes.

Each CDR used for decoding the GRS code in FIG. 2A is developed based on this message passing mechanism as well. It consists of t+1 C-nodes and N V-nodes, which matches the dimensions of a subspace parity-check matrix. Its decoding involves only a single step message transfer from the V-nodes to C-nodes and back, and is summarized in three steps: 1) syndrome calculation at all C-nodes, 2) for each V-node associated with each C-node, determine the extrinsic information, and 3) a decision is made at each V-node. The unique characteristics of this decoder lie in the final decision step: the decision is made based upon whether there is consensus extrinsic information at each V-node. If a consensus is formed, a V-node outputs the extrinsic symbol value. Otherwise, it outputs the zero value. The equations below state the mathematical operations in the 3 decoding steps that take place within a single CDR.

Let,
rⱼ−jth symbol in a received codeword
hp_{i,j}—the element at row i and column j of a subspace parity-check matrix
sᵢ—syndrome value associated with the C-node i
y_{i,j}—extrinsic message symbol from C-node i to V-node j
[symbol] —error estimate for the jth symbol.
   Then the general algorithm to be applied within a single CDR is:

$${s}_{i} = {\sum }_{j = 1}^{N} {r}_{j} \cdot {h}_{{P}_{i , j}} , \\ {y}_{i , j} = {s}_{i} \cdot {h}_{{P}_{i , j}}^{- 1} , \\ \hat{{e}_{j}} = \{ \begin{matrix}{y}_{1 , j} if {y}_{1 , j} = {y}_{2 , j} = … = {y}_{( t + 1 ) , j} \\ 0 otherwise\end{matrix}$$

After these operations, the error estimates [symbol] generated from all

$$( \begin{matrix}N \\ t - 1\end{matrix} )$$

CDRs are logically OR'd at the top level as mentioned earlier, to evaluate the final error estimate, \tilde{e}ⱼ, for each symbol location. And as the last step, this final error estimate is XOR'ed with the received vector to provide a codeword estimate.

Next is presented two example problems that illustrate the code construction and consensus decoding process for generalized Reed-Solomon (GRS) code. The next portion of this disclosure is structured as follows. First, a Galois field arithmetic will be defined, followed by an example for a 1 symbol error correction and another example of two symbol error correction.

A Galois field is denoted as GF(q), where is q is the size or number of elements of the field. This is a numerical collection of elements with a very tight mathematical structure. The examples shown in this document assume a symbol size of 4 bits or GF(2⁴). A Galois field for GF(2⁴) is defined by the so-called primitive polynomial. There can be many primitive polynomials for a particular GF(q). In this exercise, the following is chosen:

g(x)=x⁴+x+1

to span all of the elements of GF(2⁴).

Since the consensus decoding algorithm is developed for generalized Reed-Solomon code, which is a non-binary code, all the symbol additions, multiplications and inversions are defined by this primitive polynomial which are necessary to the encoding and decoding processes.

Table 1 below shows the two representations of all the symbols within the specified Galois field. The first column shows each symbol in the Galois field in its power representation and the 2nd column shows its corresponding binary representation. Note that there are a total of 1 zero element and 14 non-zero elements in the field. In general, a Galois field specified by a primitive polynomial of degree m, has n=(2^{m}−1) total number of elements.

Table 1 can also be developed by replacing the α symbol with the intermediate symbol x for all of the non-zero power representation elements and replacing the binary vectors with the degree 3 polynomial of the binary representation. Then the power representation and binary representations are related through a modulo g(x) operation for binary polynomials. For instance, for α¹¹ replaced with x¹¹ and its binary representation “1110” replaced with x³+x²+x, then

x¹¹ mod x⁴+x+1=x³+x²+x

Using this relationship, the binary representations of all of the non-zero elements can be determined. Having this lookup table defined, we can manipulate between the two different representations to perform additions, multiplications and inversions. First, GF additions of two symbols are typically performed by simply XOR'ing the corresponding binary representations element by element, where XOR is typically denoted by ⊕. For example, α⁴+α⁸=α⁵ because:

$$\frac{\begin{matrix}0 & 0 & 1 & 1 & ( {α}^{4} ) ⊕ \\ 0 & 1 & 0 & 1 & ( {α}^{5} )\end{matrix}}{\begin{matrix}0 & 1 & 1 & 0 & ( {α}^{5} )\end{matrix}}$$

For GF multiplications, the power representations in Table 1 can be used. For multiplications that involve ONLY non-zero GF elements, the following equation shows the results of multiplication:

α^{mod[a+b,a}=α^{a}α^{b}

For example, α⁴α⁸=α¹² and α⁷α⁸=α⁰. For multiplications that involve the zero element, the output is also 0.
Next, inversions of GF elements are defined as:

(α³)⁻¹=α^{n-a}

| Power Representation | Binary Representation |
|---|---|
| 0 | 0 0 0 0 |
| α⁰ | 0 0 0 1 |
| α¹ | 0 0 1 0 |
| α² | 0 1 0 0 |
| α³ | 1 0 0 0 |
| α⁴ | 0 0 1 1 |
| α⁵ | 0 1 1 0 |
| α⁶ | 1 1 0 0 |
| α⁷ | 1 0 1 1 |
| α⁸ | 0 1 0 1 |
| α⁹ | 1 0 1 0 |
| α¹⁰ | 0 1 1 1 |
| α¹¹ | 1 1 1 0 |
| α¹² | 1 1 1 1 |
| α¹³ | 1 1 0 1 |
| α¹⁴ | 1 0 0 1 |

Table 1: Galois Field Representations for g(x)=x⁴+x+1
Having the basis of the Galois field arithmetic developed, this disclosure can now go through the basic general consensus decoding algorithm and then some examples that illustrate the code construction and consensus decoding algorithm.

The first example is to illustrate 1 symbol error correction. In this example, a (N=10, K=8) GRS code is assumed, where N is the number of codeword symbols and K is the number of information symbols in the codeword. Note that for maximum distance separable code, the following equation holds:

N=K+2t

where 2t is the number of parity symbols and t is the error correction capability of the code (in other words, maximum number of symbols that can be correctable in the event of errors). For our example here, there are N−K=2 parity symbols, therefore t=1 and the code can correct for at most a single symbol error. Now let's go through the steps in how to first construct the parity-check matrix of the code and then go through the decoding process.

The disclosure now steps through the operations to perform parity-check matrix construction. The first step is to construct the H matrix. The H matrix for the code dimensions specified in this example is developed based on the following equation:

$$H = {[ \begin{matrix}z & • & {x}^{0} \\ z & • & {x}^{1}\end{matrix} ]}_{2 \times 10} ,$$

where o denotes the Hadamard product. If we set randomly but following the constraints for z and x specified in paragraph [0032]:

$$\begin{matrix}z = [ {α}^{2} & {α}^{0} & {α}^{2} & {α}^{1} & {α}^{6} & {α}^{4} & {α}^{14} & {α}^{3} & {α}^{3} & {α}^{12} ] \\ x = [ {α}^{4} & {α}^{6} & {α}^{3} & {α}^{0} & {α}^{1} & {α}^{5} & {α}^{8} & {α}^{14} & {α}^{11} & {α}^{10} ]\end{matrix}$$

$$Then , \\ \begin{matrix}H = [ \begin{matrix}\begin{matrix}{{α}^{2} ( {α}^{4} )}^{0} & {{α}^{0} ( {α}^{6} )}^{0} & {{α}^{2} ( {α}^{3} )}^{0} & {{α}^{1} ( {α}^{6} )}^{0} & {{α}^{6} ( {α}^{1} )}^{0} & {{α}^{4} ( {α}^{5} )}^{0} & {{α}^{14} ( {α}^{8} )}^{0} & {{α}^{3} ( {α}^{14} )}^{0} & {{α}^{3} ( {α}^{11} )}^{0} & {{α}^{12} ( {α}^{10} )}^{0}\end{matrix} \\ \begin{matrix}{{α}^{2} ( {α}^{4} )}^{1} & {{α}^{0} ( {α}^{6} )}^{1} & {{α}^{2} ( {α}^{3} )}^{1} & {{α}^{1} ( {α}^{6} )}^{1} & {{α}^{6} ( {α}^{1} )}^{1} & {{α}^{4} ( {α}^{5} )}^{1} & {{α}^{14} ( {α}^{8} )}^{1} & {{α}^{3} ( {α}^{14} )}^{1} & {{α}^{3} ( {α}^{11} )}^{1} & {{α}^{12} ( {α}^{10} )}^{1}\end{matrix}\end{matrix} ] \\ = [ \begin{matrix}{α}^{2} & {α}^{0} & {α}^{2} & {α}^{1} & {α}^{6} & {α}^{4} & {α}^{14} & {α}^{3} & {α}^{3} & {α}^{12} \\ {α}^{6} & {α}^{6} & {α}^{5} & {α}^{1} & {α}^{7} & {α}^{9} & {α}^{7} & {α}^{2} & {α}^{14} & {α}^{7}\end{matrix} ]\end{matrix}$$

The next step is to construct

$$( \begin{matrix}N \\ t - 1\end{matrix} )$$

subspace H matrices. Since

$$( \begin{matrix}N \\ t - 1\end{matrix} ) = ( \begin{matrix}10 \\ 0\end{matrix} ) = 1$$

for this example, there is only 1 subspace H matrix, Hₚ, and as mentioned in paragraph [0034], this is the same as the original H matrix:

$${H}_{p} = H = [ \begin{matrix}{α}^{2} & {α}^{0} & {α}^{2} & {α}^{1} & {α}^{6} & {α}^{4} & {α}^{14} & {α}^{3} & {α}^{3} & {α}^{12} \\ {α}^{6} & {α}^{6} & {α}^{5} & {α}^{1} & {α}^{7} & {α}^{9} & {α}^{7} & {α}^{2} & {α}^{14} & {α}^{7}\end{matrix} ]$$

The inverse of Hₚ will be required in the decoding process and it is defined here also:

$${H}_{p}^{- 1} = [ \begin{matrix}{α}^{13} & {α}^{0} & {α}^{13} & {α}^{14} & {α}^{9} & {α}^{11} & {α}^{1} & {α}^{12} & {α}^{12} & {α}^{3} \\ {α}^{9} & {α}^{9} & {α}^{10} & {α}^{14} & {α}^{8} & {α}^{6} & {α}^{8} & {α}^{13} & {α}^{1} & {α}^{8}\end{matrix} ]$$

where the element by element inverse is denoted by (•)⁻¹.

Given the set of subspace H matrices, we can decode an erred codeword using the consensus decoding algorithm. But before we get into the decoding process, we first need to generate an example codeword and purposely inject an error into one of the symbol positions of this codeword.

Next is discussed an example codeword construction and channel corruption process. To create a codeword, the disclosure first finds the generator matrix, G, given H through standard technique often called a systematic representation:

$$G = [ \begin{matrix}{α}^{0} & 0 & 0 & 0 & 0 & 0 & 0 & 0 & {α}^{0} & {α}^{4} \\ 0 & {α}^{0} & 0 & 0 & 0 & 0 & 0 & 0 & {α}^{5} & {α}^{5} \\ 0 & 0 & {α}^{0} & 0 & 0 & 0 & 0 & 0 & {α}^{12} & {α}^{11} \\ 0 & 0 & 0 & {α}^{0} & 0 & 0 & 0 & 0 & {α}^{4} & {α}^{2} \\ 0 & 0 & 0 & 0 & {α}^{0} & 0 & 0 & 0 & {α}^{12} & {α}^{1} \\ 0 & 0 & 0 & 0 & 0 & {α}^{0} & 0 & 0 & {α}^{2} & {α}^{11} \\ 0 & 0 & 0 & 0 & 0 & 0 & {α}^{0} & 0 & {α}^{13} & {α}^{10} \\ 0 & 0 & 0 & 0 & 0 & 0 & 0 & {α}^{0} & {α}^{12} & {α}^{2}\end{matrix} ] .$$

Note that the standard derivation from H to G is not shown here. The standard derivation is not a focus of the present disclosure but it is necessary to define the generator matrix so that a codeword example can be generated for decoding illustration.
An example codeword that lies in this code space is:

c=[α⁰ 0 0 0 0 0 0 α² α⁴].

If the channel corrupts the codeword and introduces a random error at the 5th symbol position represented by the following error vector:

e=[0 0 0 0 α⁹ 0 0 0 0 0]

Then the received/retrieved pattern becomes:

r=c+e=[α⁰ 0 0 0 α⁹ 0 0 0 α² α⁴].

FIG. 2B illustrates a simplified diagram of the consensus decoding process 200B that is applicable for a (10, 8) GRS Code. FIG. 2B shows the consensus decoder 201 and combiners 203, 205, 207 and 209.

Step 1 in the decoding process is to calculate the syndrome using the 1^{st} equation in paragraph [0041]:

$${s}_{1} = {\sum }_{j = 1}^{10} {r}_{j} \cdot {h}_{{P}_{1 , j}} = {α}^{6} {α}^{2} + 0 {α}^{0} + 0 {α}^{2} + 0 {α}^{1} + {α}^{9} {α}^{6} + 0 {α}^{4} + 0 {α}^{14} + 0 {α}^{3} + {α}^{2} {α}^{3} + {α}^{4} {α}^{12} = {α}^{6}$$

$${s}_{2} = {\sum }_{j = 1}^{10} {r}_{j} \cdot {h}_{{P}_{2 , j}} = {α}^{6} {α}^{6} + 0 {α}^{6} + 0 {α}^{5} + 0 {α}^{1} + {α}^{9} {α}^{7} + 0 {α}^{9} + 0 {α}^{7} + 0 {α}^{2} + {α}^{2} {α}^{14} + {α}^{4} {α}^{7} = {α}^{1}$$

$$s = [ \begin{matrix}{α}^{6} & {α}^{1}\end{matrix} ]$$

Step 2 involves calculating extrinsic information by applying the 2^{nd} equation in paragraph [0041] to produce:

$${y}_{i , j} = {s}_{i} \cdot {h}_{{P}_{1 , j}}^{- 1}$$

$$\begin{matrix}y = [ \begin{matrix}\begin{matrix}{α}^{0} {α}^{13} & {α}^{0} {α}^{0} & {α}^{0} {α}^{13} & {α}^{0} {α}^{14} & {α}^{0} {α}^{9} & {α}^{0} {α}^{11} & {α}^{0} {α}^{1} & {α}^{0} {α}^{12} & {α}^{0} {α}^{12} & {α}^{0} {α}^{3}\end{matrix} \\ \begin{matrix}{α}^{1} {α}^{9} & {α}^{1} {α}^{9} & {α}^{1} {α}^{10} & {α}^{1} {α}^{14} & {α}^{1} {α}^{8} & {α}^{1} {α}^{6} & {α}^{1} {α}^{8} & {α}^{1} {α}^{13} & {α}^{1} {α}^{1} & {α}^{1} {α}^{8}\end{matrix}\end{matrix} ] \\ = [ \begin{matrix}{α}^{13} & {α}^{0} & {α}^{13} & {α}^{14} & {α}^{9} & {α}^{11} & {α}^{1} & {α}^{12} & {α}^{12} & {α}^{3} \\ {α}^{10} & {α}^{10} & {α}^{11} & {α}^{0} & {α}^{9} & {α}^{7} & {α}^{9} & {α}^{14} & {α}^{2} & {α}^{9}\end{matrix} ] \end{matrix}$$

Step 3 involves performing consensus decoding using the last equation in paragraph [0041]. If all elements in each column of y form a consensus, i.e. they all agree on the same symbol, set error estimate,

[symbol]

=y_{1,j}, else start êⱼ=0;

Then the error estimate from the CDR becomes:

ê=[0 0 0 α⁹ 0 0 0 0 0]

Step 4 involves OR'ing error estimates from all consensus decoders (CDR)s. Since there is only 1 CDR in this case for single error correction code, the result becomes:

\tilde{e}=ê=[0 0 0 0 α⁹ 0 0 0 0 0]

Step 5 includes estimating the codeword as follows:

$$\begin{matrix}\tilde{c} = r + \tilde{e} \\ \end{matrix} \begin{matrix}= [ {α}^{6} + 0 \; 0 + 0 \; 0 + 0 \; 0 + 0 {α}^{9} + {α}^{9} 0 + 0 \; 0 + 0 \; 0 + 0 {α}^{2} + 0 {α}^{4} + 0 ] \\ = [ {α}^{0} 0 \; 0 \; 0 \; 0 \; 0 \; 0 \; 0 {α}^{2} {α}^{4} ]\end{matrix}$$

At this point, the algorithm has successfully corrected for the single symbol error using a single symbol error correction code.

The next example is for a 2 symbol error correction. In this example, it is assumed that there is a (N=6, K=2) GRS code. In this case, there are N−K=4 parity symbols, therefore t=2 and the code can correct for at most two symbols in error. The algorithm follows similar step as above to construct the H matrix of the code.

The first portion of the algorithm performs parity-check matrix construction. First, the method constructs an H matrix. If we set randomly but following the constraints for z and x specified in paragraph [0032]:

$$\begin{matrix}z = [ {α}^{5} & {α}^{1} & {α}^{6} & {α}^{0} & {α}^{13} & {α}^{13} ] \\ x = [ {α}^{0} & {α}^{3} & {α}^{10} & {α}^{11} & {α}^{1} & {α}^{5} ]\end{matrix}$$

$$Then , \begin{matrix}H = [ \begin{matrix}{{α}^{5} ( {α}^{0} )}^{0} & {{α}^{1} ( {α}^{3} )}^{0} & {{α}^{6} ( {α}^{10} )}^{0} & {{α}^{0} ( {α}^{11} )}^{0} & {{α}^{13} ( {α}^{1} )}^{0} & {{α}^{13} ( {α}^{5} )}^{0} \\ {{α}^{5} ( {α}^{0} )}^{1} & {{α}^{1} ( {α}^{3} )}^{1} & {{α}^{6} ( {α}^{10} )}^{1} & {{α}^{0} ( {α}^{11} )}^{1} & {{α}^{13} ( {α}^{1} )}^{1} & {{α}^{13} ( {α}^{5} )}^{1} \\ {{α}^{5} ( {α}^{0} )}^{2} & {{α}^{1} ( {α}^{3} )}^{2} & {{α}^{6} ( {α}^{10} )}^{2} & {{α}^{0} ( {α}^{11} )}^{2} & {{α}^{13} ( {α}^{1} )}^{2} & {{α}^{13} ( {α}^{5} )}^{2} \\ {{α}^{5} ( {α}^{0} )}^{3} & {{α}^{1} ( {α}^{3} )}^{3} & {{α}^{6} ( {α}^{10} )}^{3} & {{α}^{0} ( {α}^{11} )}^{3} & {{α}^{13} ( {α}^{1} )}^{3} & {{α}^{13} ( {α}^{5} )}^{3}\end{matrix} ] \\ = [ \begin{matrix}{α}^{5} & {α}^{1} & {α}^{6} & {α}^{6} & {α}^{13} & {α}^{13} \\ {α}^{5} & {α}^{4} & {α}^{1} & {α}^{11} & {α}^{14} & {α}^{3} \\ {α}^{5} & {α}^{7} & {α}^{11} & {α}^{7} & {α}^{0} & {α}^{8} \\ {α}^{5} & {α}^{10} & {α}^{6} & {α}^{3} & {α}^{1} & {α}^{13}\end{matrix} ]\end{matrix}$$

The next step is to construct

$$( \begin{matrix}N \\ t - 1\end{matrix} )$$

subspace H matrices. Since

$$( \begin{matrix}N \\ t - 1\end{matrix} ) = ( \begin{matrix}6 \\ 1\end{matrix} ) = 6 ,$$

there are 6 subspace H matrices, H_{P}⁽¹⁾, H_{P}⁽²⁾, H_{P}⁽³⁾, H_{P}⁽⁴⁾, H_{P}⁽⁵⁾ and H_{P}⁽⁶⁾.

As an example, the following illustrates one of the ways to find H_{P}⁽¹⁾ through the steps below. Since for this particular case one tries to eliminate elements in column 1, x₁ that forms the H matrix above is used. In general, xᵢ would be used for column i.
The steps are as follows.
1) Multiply 1st row of H by x₁ and add to 2nd row to generate 1st row of H_{P}⁽¹⁾:

$$[ \begin{matrix}{α}^{5} & {α}^{1} & {α}^{6} & {α}^{0} & {α}^{13} & {α}^{13} \\ {α}^{5} & {α}^{4} & {α}^{1} & {α}^{11} & {α}^{14} & {α}^{3} \\ {α}^{5} & {α}^{7} & {α}^{11} & {α}^{7} & {α}^{0} & {α}^{8} \\ {α}^{5} & {α}^{10} & {α}^{6} & {α}^{3} & {α}^{1} & {α}^{13}\end{matrix} ] \begin{matrix}{α}^{0} \\ \\ \\ \end{matrix} \sim [ \begin{matrix}0 & {α}^{0} & {α}^{11} & {α}^{12} & {α}^{2} & {α}^{8}\end{matrix} ]$$

2) Multiply 2nd row of H by x₁ and add to 3rd row to generate 2nd row of H_{P}⁽¹⁾:

$$[ \begin{matrix}{α}^{5} & {α}^{1} & {α}^{6} & {α}^{0} & {α}^{13} & {α}^{13} \\ {α}^{5} & {α}^{4} & {α}^{1} & {α}^{11} & {α}^{14} & {α}^{3} \\ {α}^{5} & {α}^{7} & {α}^{11} & {α}^{7} & {α}^{0} & {α}^{8} \\ {α}^{5} & {α}^{10} & {α}^{6} & {α}^{3} & {α}^{1} & {α}^{13}\end{matrix} ] \begin{matrix} \\ {α}^{0} \\ \\ \end{matrix} \sim [ \begin{matrix}0 & {α}^{3} & {α}^{6} & {α}^{8} & {α}^{3} & {α}^{13}\end{matrix} ]$$

3) Multiply 3rd row of H by x₁ and add to 4th row to generate 3rd row of H_{P}⁽¹⁾:

$$[ \begin{matrix}{α}^{5} & {α}^{1} & {α}^{6} & {α}^{0} & {α}^{13} & {α}^{13} \\ {α}^{5} & {α}^{4} & {α}^{1} & {α}^{11} & {α}^{14} & {α}^{3} \\ {α}^{5} & {α}^{7} & {α}^{11} & {α}^{7} & {α}^{0} & {α}^{8} \\ {α}^{5} & {α}^{10} & {α}^{6} & {α}^{3} & {α}^{1} & {α}^{13}\end{matrix} ] \begin{matrix} \\ \\ {α}^{0} \\ \end{matrix} \sim [ \begin{matrix}0 & {α}^{6} & {α}^{1} & {α}^{4} & {α}^{4} & {α}^{3}\end{matrix} ]$$

4) Construct subspace H matrix:

$${H}_{P}^{( 1 )} = [ \begin{matrix}0 & {α}^{0} & {α}^{11} & {α}^{12} & {α}^{2} & {α}^{8} \\ 0 & {α}^{3} & {α}^{6} & {α}^{8} & {α}^{3} & {α}^{13} \\ 0 & {α}^{6} & {α}^{1} & {α}^{4} & {α}^{4} & {α}^{3}\end{matrix} ]$$

Note that the above procedure is equivalent to evaluating the equation provided in paragraph [0034]: h_{P}_{_{i,j}}^{(A}^{ⱼ}⁾=Hₖ₌₁ⁱ⁻¹(xₐ_{ₖ}+xⱼ)·h_{i,j}
By a similar method, all the other subspace H matrices are found and listed below:

$${H}_{P}^{( 2 )} = [ \begin{matrix}{α}^{4} & 0 & {α}^{3} & {α}^{5} & {α}^{7} & {α}^{9} \\ {α}^{4} & 0 & {α}^{13} & {α}^{1} & {α}^{8} & {α}^{14} \\ {α}^{4} & 0 & {α}^{8} & {α}^{12} & {α}^{9} & {α}^{4}\end{matrix} ]$$

$${H}_{P}^{( 3 )} = [ \begin{matrix}{α}^{10} & {α}^{13} & 0 & {α}^{14} & {α}^{6} & {α}^{13} \\ {α}^{10} & {α}^{1} & 0 & {α}^{10} & {α}^{7} & {α}^{3} \\ {α}^{10} & {α}^{4} & 0 & {α}^{6} & {α}^{8} & {α}^{8}\end{matrix} ]$$

$${H}_{P}^{( 4 )} = [ \begin{matrix}{α}^{2} & {α}^{6} & {α}^{5} & 0 & {α}^{4} & {α}^{1} \\ {α}^{2} & {α}^{9} & {α}^{0} & 0 & {α}^{5} & {α}^{6} \\ {α}^{2} & {α}^{12} & {α}^{10} & 0 & {α}^{6} & {α}^{11}\end{matrix} ]$$

$${H}_{P}^{( 5 )} = [ \begin{matrix}{α}^{9} & {α}^{10} & {α}^{14} & {α}^{6} & 0 & {α}^{0} \\ {α}^{9} & {α}^{13} & {α}^{9} & {α}^{2} & 0 & {α}^{5} \\ {α}^{9} & {α}^{1} & {α}^{4} & {α}^{13} & 0 & {α}^{10}\end{matrix} ]$$

$${H}_{P}^{( 6 )} = [ \begin{matrix}{α}^{0} & {α}^{12} & {α}^{6} & {α}^{3} & {α}^{0} & 0 \\ {α}^{0} & {α}^{0} & {α}^{1} & {α}^{14} & {α}^{1} & 0 \\ {α}^{0} & {α}^{3} & {α}^{11} & {α}^{10} & {α}^{2} & 0\end{matrix} ]$$

Again, the inverse of each element in H_{P}⁽ⁱ⁾ will be required in the decoding process and so we define them here also:

$$\begin{matrix}{[ {H}_{P}^{( 1 )} ]}^{- 1} = [ \begin{matrix}0 & {α}^{0} & {α}^{4} & {α}^{3} & {α}^{13} & {α}^{7} \\ 0 & {α}^{12} & {α}^{9} & {α}^{7} & {α}^{12} & {α}^{2} \\ 0 & {α}^{9} & {α}^{14} & {α}^{11} & {α}^{11} & {α}^{12}\end{matrix} ] \\ {[ {H}_{P}^{( 2 )} ]}^{- 1} = [ \begin{matrix}{α}^{11} & 0 & {α}^{12} & {α}^{10} & {α}^{8} & {α}^{6} \\ {α}^{11} & 0 & {α}^{2} & {α}^{14} & {α}^{7} & {α}^{1} \\ {α}^{11} & 0 & {α}^{7} & {α}^{3} & {α}^{6} & {α}^{11}\end{matrix} ] \\ {[ {H}_{P}^{( 3 )} ]}^{- 1} = [ \begin{matrix}{α}^{5} & {α}^{2} & 0 & {α}^{1} & {α}^{9} & {α}^{2} \\ {α}^{5} & {α}^{14} & 0 & {α}^{5} & {α}^{8} & {α}^{12} \\ {α}^{5} & {α}^{11} & 0 & {α}^{9} & {α}^{7} & {α}^{7}\end{matrix} ] \\ {[ {H}_{P}^{( 4 )} ]}^{- 1} = [ \begin{matrix}{α}^{13} & {α}^{9} & {α}^{10} & 0 & {α}^{11} & {α}^{14} \\ {α}^{13} & {α}^{6} & {α}^{0} & 0 & {α}^{10} & {α}^{9} \\ {α}^{13} & {α}^{3} & {α}^{5} & 0 & {α}^{9} & {α}^{4}\end{matrix} ] \\ {[ {H}_{P}^{( 5 )} ]}^{- 1} = [ \begin{matrix}{α}^{6} & {α}^{5} & {α}^{1} & {α}^{9} & 0 & {α}^{0} \\ {α}^{6} & {α}^{2} & {α}^{6} & {α}^{13} & 0 & {α}^{10} \\ {α}^{6} & {α}^{14} & {α}^{11} & {α}^{2} & 0 & {α}^{5}\end{matrix} ] \\ {[ {H}_{P}^{( 6 )} ]}^{- 1} = [ \begin{matrix}{α}^{0} & {α}^{3} & {α}^{9} & {α}^{12} & {α}^{0} & 0 \\ {α}^{0} & {α}^{0} & {α}^{14} & {α}^{1} & {α}^{14} & 0 \\ {α}^{0} & {α}^{12} & {α}^{4} & {α}^{5} & {α}^{13} & 0\end{matrix} ]\end{matrix}$$

where the element by element inverse is denoted by (•)⁻¹.

Given the set of subspace H matrices, the system can decode an erred codeword using the consensus decoding algorithm. But before discussing the decoding process, the disclosure first describes generating an example codeword and purposely injecting errors into the codeword.

Next is presented an example codeword construction and channel corruption. To create a codeword, one first finds the generator matrix, G, given H through standard technique (systematic representation):

$$G = [ \begin{matrix}{α}^{0} & 0 & {α}^{3} & {α}^{1} & {α}^{3} & {α}^{8} \\ 0 & {α}^{0} & {α}^{13} & {α}^{10} & {α}^{0} & {α}^{9}\end{matrix} ] .$$

Note that the standard derivation from H to G is not shown here because it is not the focus of the disclosure. But, it is necessary to define this generator matrix so that a codeword example can be generated for decoding illustration.
An example codeword that lies in this code space is:

c=[α⁰ 0 α³ α¹ α³ α⁸]

If the channel corrupts the codeword and introduces two random symbol errors at the 2nd and 5th symbol positions represented by the following error vector:

e=[0 α³ 0 0 α⁹ 0]

Then the received/retrieved pattern becomes:

r=c+e=[α⁰ α³ α³ α¹ α¹ α⁸]

The consensus decoding process for the 2^{nd} example is discussed next. For this particular example here, the consensus decoding block diagram is simplified to FIG. 2C, that is applicable for a (6, 2) GRS Code.

Step 1 in the decoding process is to calculate syndrome using the 1^{st} equation in paragraph [0041]:
Consensus Decoder 1 (220):

$${s}_{1} = {\sum }_{j = 1}^{6} {r}_{j} \cdot {h}_{{P}_{1 , j}}^{( 1 )} = {α}^{0} 0 + {α}^{3} {α}^{0} + {α}^{3} {α}^{11} + {α}^{1} {α}^{12} + {α}^{1} {α}^{2} + {α}^{8} {α}^{8}$$

$${s}_{2} = {\sum }_{j = 1}^{6} {r}_{j} \cdot {h}_{{P}_{2 , j}}^{( 1 )} = {α}^{0} 0 + {α}^{3} {α}^{3} + {α}^{3} {α}^{6} + {α}^{1} {α}^{8} + {α}^{1} {α}^{3} + {α}^{8} {α}^{13}$$

$${s}_{3} = {\sum }_{j = 1}^{6} {r}_{j} \cdot {h}_{{P}_{3 , j}}^{( 1 )} = {α}^{0} 0 + {α}^{3} {α}^{6} + {α}^{3} {α}^{1} + {α}^{1} {α}^{4} + {α}^{1} {α}^{4} + {α}^{8} {α}^{3}$$

$${s}^{( 1 )} = [ \begin{matrix}{α}^{5} & {α}^{4} & {α}^{10}\end{matrix} ]$$

Consensus Decoder 2 (222):

s⁽²⁾=[α¹ α² α³]
Consensus Decoder 3 (224):

s⁽³⁾=[α⁴ α⁰ α¹²]
Consensus Decoder 4 (226):

s⁽⁴⁾=[α¹⁰ α⁵ 0]
Consensus Decoder 5 (228):

s⁽⁵⁾=[α¹³ α¹ α⁴]
Consensus Decoder 6 (230):

s⁽⁶⁾=[α⁷ α¹² α¹]

Step 2 involves calculating extrinsic information by applying the2^{nd} equation in paragraph [0041] to produce:

y_{i,j}^{(k)}=sᵢ^{(k)}·[h_{P}_{_{i,j}}^{(k)}]⁻¹
Consensus Decoder 1:

$${y}^{( 1 )} = [ \begin{matrix}0 & {α}^{5} & {α}^{9} & {α}^{8} & {α}^{3} & {α}^{12} \\ 0 & {α}^{1} & {α}^{13} & {α}^{11} & {α}^{1} & {α}^{6} \\ 0 & {α}^{4} & {α}^{9} & {α}^{6} & {α}^{6} & {α}^{7}\end{matrix} ]$$

Consensus Decoder 2:

$${y}^{( 2 )} = [ \begin{matrix}{α}^{12} & 0 & {α}^{13} & {α}^{11} & {α}^{9} & {α}^{7} \\ {α}^{13} & 0 & {α}^{4} & {α}^{1} & {α}^{9} & {α}^{3} \\ {α}^{14} & 0 & {α}^{10} & {α}^{6} & {α}^{9} & {α}^{14}\end{matrix} ]$$

Consensus Decoder 3:

$${y}^{( 3 )} = [ \begin{matrix}{α}^{9} & {α}^{6} & 0 & {α}^{5} & {α}^{13} & {α}^{6} \\ {α}^{5} & {α}^{14} & 0 & {α}^{5} & {α}^{8} & {α}^{12} \\ {α}^{2} & {α}^{8} & 0 & {α}^{6} & {α}^{4} & {α}^{4}\end{matrix} ]$$

Consensus Decoder 4:

$${y}^{( 4 )} = [ \begin{matrix}{α}^{8} & {α}^{4} & {α}^{5} & 0 & {α}^{6} & {α}^{9} \\ {α}^{3} & {α}^{11} & {α}^{5} & 0 & {α}^{0} & {α}^{14} \\ 0 & 0 & 0 & 0 & 0 & 0\end{matrix} ]$$

Consensus Decoder 5:

$${y}^{( 5 )} = [ \begin{matrix}{α}^{4} & {α}^{3} & {α}^{14} & {α}^{7} & 0 & {α}^{13} \\ {α}^{7} & {α}^{3} & {α}^{7} & {α}^{14} & 0 & {α}^{11} \\ {α}^{10} & {α}^{3} & {α}^{0} & {α}^{6} & 0 & {α}^{9}\end{matrix} ]$$

Consensus Decoder 6:

$${y}^{( 6 )} = [ \begin{matrix}{α}^{7} & {α}^{10} & {α}^{1} & {α}^{4} & {α}^{7} & 0 \\ {α}^{12} & {α}^{12} & {α}^{11} & {α}^{13} & {α}^{11} & 0 \\ {α}^{1} & {α}^{13} & {α}^{5} & {α}^{6} & {α}^{14} & 0\end{matrix} ]$$

Step 3 involves performing consensus decoding using the last equation in paragraph [0041]. If all elements in each column of y form a consensus, i.e. they all agree on the same symbol, set error estimate,

[symbol]

^{(k)}=y_{1,j}^{(k)}, else set [symbol] ^{(k)}=0;

Then the error estimate from each CDR becomes:
Consensus Decoder 1:

ê⁽¹⁾=[0 0 0 0 0 0]
Consensus Decoder 2:

ê⁽²⁾=[0 0 0 0 α⁹ 0]
Consensus Decoder 3:

ê⁽³⁾=[0 0 0 0 0 0]
Consensus Decoder 4:

ê⁽⁴⁾=[0 0 0 0 0 0]
Consensus Decoder 5:

ê⁽⁵⁾=[0 α³ 0 0 0 0]

Consensus Decoder 6:

ê⁽⁶⁾=[0 0 0 0 0 0]

Step 4 includes “OR”ing error estimates (232, 234, 236, 238, 240, 242) from all consensus decoders.

\tilde{e}=ê⁽¹⁾Vê⁽²⁾Vê⁽³⁾Vê⁽⁴⁾Vê⁽⁵⁾Vê⁽⁶⁾=[0 α³ 0 0 α⁹ 0]

where V indicates a logical “OR” operation.

Step 5 includes estimating the codeword (244, 246, 248, 250, 252, 254).

$$\begin{matrix}\tilde{c} = r + \tilde{e} \\ = [ \begin{matrix}{α}^{0} + 0 & {α}^{3} + {α}^{3} & {α}^{3} + 0 & {α}^{1} + 0 & {α}^{1} + {α}^{9} & {α}^{8} + 0 ]\end{matrix} \\ = [ \begin{matrix}{α}^{0} & 0 & {α}^{3} & {α}^{1} & {α}^{3} & {α}^{8} ]\end{matrix}\end{matrix}$$

The algorithm at this point has successfully corrected for two random symbols in error using a two symbol error correction code.

In sum, the code construction and the consensus decoding process for exemplary codes including a (10, 8) GRS code and a (6, 2) GRS code with symbol size of 4 bits have been presented. This code construction method and consensus decoding algorithm can be applied to different code dimensions and error correction capability.

Currently, an EDAC is generated in the form of a FPGA core to demonstrate the full error correction functionality of the CDA. This core implements a highly parallelized encoder and decoder for the generalized Reed-Solomon code. For encoding, the core takes a parallel data bus, performs mathematical operations, and outputs the gated data bus along with the corresponding parity symbols, which together known as the codeword. For decoding, the core reads in the codeword bus, estimates and corrects potential data corruption up to the error correction capability defined by the code, and finally outputs the gated estimation of the codeword along with a status bit that indicates whether the output is a valid estimation.

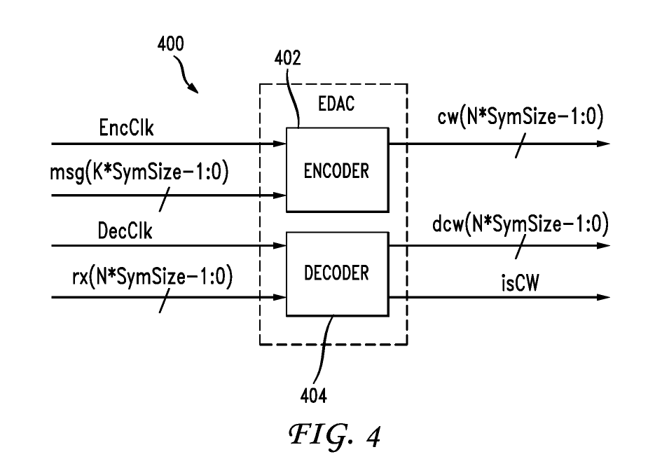

FIG. 4 shows the interface diagram 400 for error detection and correction (EDAC). Included in the core diagram 400 are an encoder 402 and a decoder 404. The signals and parameters shown in the diagram are briefly described below.

The parameters include N as the total number of symbols in a codeword, K as the number of information symbols in a codeword, and SymSize as the number of bits per codeword symbol. In the signal description, EncClk, is the master clock for the encoder, msg is the message pattern fed into the encoder, cw is the gated codeword from the encoder, DecClk is the master clock for the decoder, rx is the received pattern fed into the decoder, dCW is the gated decoded pattern from the decoder, and isCW is the status bit that indicates whether the decoded pattern is a codeword. A “1” indicates a codeword, and a “0” otherwise. The current implementation of the core is designed to restrict the clock latency performance to one cycle, where the output signal bus cw and dCW appear one clock cycle after the corresponding input. The architecture implements both the encoder and decoder as pure combinational logic and gate the output buses at the end. Due to the logic delay, the clock speed is limited. In the event that higher clock speed is desired, the core can be modified to insert additional pipeline stages to meet the timing requirement.

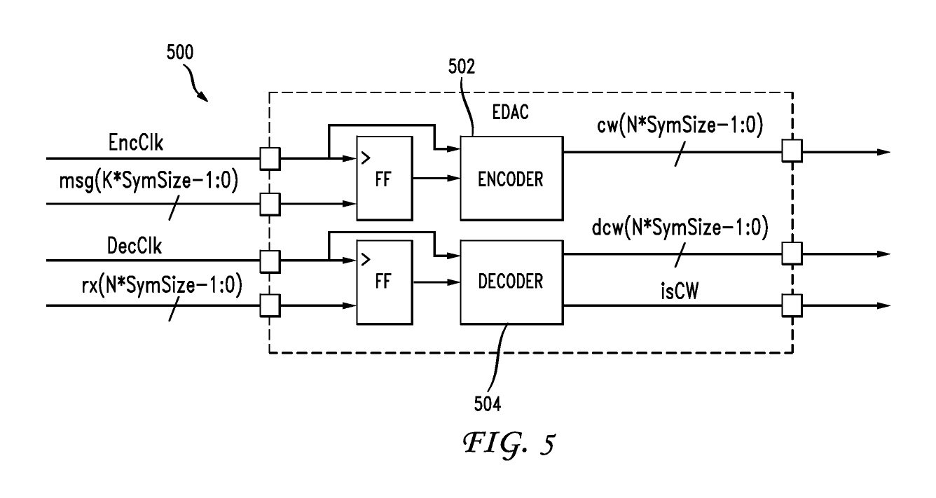

To characterize the maximum clock speed and resource utilization of the EDAC on an FPGA, synchronous flip-flops are added at the input of the data bus for both the encoder 502 and decoder 504 as shown in the arrangement 500 in FIG. 5. The flip-flops are required so that period constraint specified for the master clocks can be applied to the combinational logic paths for the encoder and decoder. The following describes the setup that was used to characterize the speed and resource utilization of the EDAC: All inputs and outputs of the encoder and decoder are routed to I/O pins of the FPGA for performance testing. The EDAC is assumed to interface with signals external to the FPGA device. Synchronous flip-flops are added at the input of the data bus for both encoder and decoder. The only timing constraint applied is clock period constraint. The maximum clock speed is obtained with the instantiation of both encoder and decoder. Encoder resource utilization is obtained with the standalone encoder and likewise for the decoder.

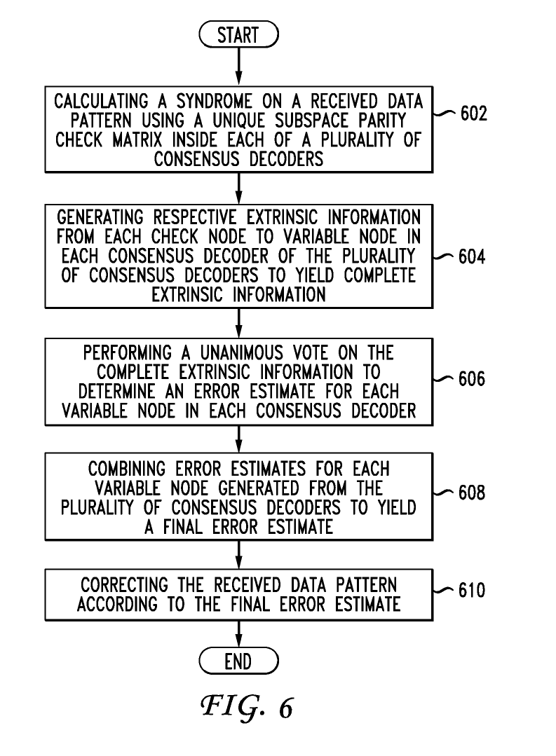

FIG. 6 illustrates a method embodiment carried out on a decoder. The method includes calculating a syndrome on a received data pattern using a unique subspace parity-check matrix inside each of a plurality of consensus decoders (602). The method includes generating respective extrinsic information from each check node to variable node in each consensus decoder of the plurality of consensus decoders to yield complete extrinsic information (604) and performing a unanimous vote on the complete extrinsic information to determine an error estimate for each variable node in each consensus decoder (606). The method further includes combining error estimates for each variable node generated from the plurality of consensus decoders to yield a final error estimate (608) and correcting a data pattern according to the final error estimate (610).

The disclosure also details a complete design and testing effort that was successfully demonstrated and implemented, outlines the theory behind the algorithm, and provides comparisons with existing algorithms. The general conclusion is that in comparison to the BM algorithm, the CDA is more complex, primarily due to the fact that the BM algorithm is a serial processing decoder while the CDA is a parallel algorithm. The choice of which algorithm to recommend depends on the application. For high-speed bus applications with small error correction requirement, the CDA is a good choice, while for serial bitstream applications, the BM algorithm may be the better choice. Thus, CDA can be a viable solution for many high-speed databus applications. Also, many spacecraft hardware requirements for t=2 symbol corrections exist for which the CDA is a good candidate. The applications generally fall into the error detection and correction (EDAC) units of spacecraft or other applications. The CDA is a direct result of the need to provide the function to light CPUs and on-board signal processing units to mitigate single event upsets.

Embodiments within the scope of the present disclosure may also include tangible and/or non-transitory computer-readable storage devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform particular tasks or implement particular abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other embodiments of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

The various embodiments described above are provided by way of illustration only and should not be construed to limit the scope of the disclosure. Various modifications and changes may be made to the principles described herein without following the example embodiments and applications illustrated and described herein, and without departing from the spirit and scope of the disclosure. For example, measurements from various other types of data sources can be included within the analysis. Virtual optical and acceleration measurements of keystrokes or chair movement, for example, can be provided. The number of different data streams can be two, three, four, five or more depending on the necessary circumstances. As noted above, a “processor” can be part of essentially any kind of device such as a refrigerator, a copier, a wearable device such as a watch, hearing aid, pacemaker, jewelry, etc. Furthermore, a device can be an enclosure such as a room, which “device” can have more than one reporting pathway. The boundary of a device or an enclosure is a data stream or a processor and the reporting pathways represent the boundary of a device or enclosure. Claim language reciting “at least one of” a set indicates that one member of the set or multiple members of the set satisfy the claim.

We claim:

1. A method comprising:
calculating, via a processor, a syndrome on a received data pattern using a unique subspace parity-check matrix inside each of a plurality of consensus decoders;
generating respective extrinsic information from each check node to variable node in each consensus decoder of the plurality of consensus decoders to yield complete extrinsic information;
performing a vote on the complete extrinsic information to determine an error estimate for each variable node in each consensus decoder;
combining error estimates for each variable node generated from the plurality of consensus decoders to yield a final error estimate; and
correcting the received data pattern according to the final error estimate.

2. The method of claim 1, wherein the unique subspace parity-check matrix is associated with a generalized Reed-Solomon code.

3. The method of claim 1, wherein performing the vote further comprises performing a unanimous vote.

4. The method of claim 1, wherein performing the vote to determine the error estimate further comprises applying a consensus decoding algorithm to determine the value of a received symbol by combining results of a plurality of N consensus decoders which produces an error estimate associated with each received symbol location.

5. The method of claim 4, wherein performing the combining to determine an error estimate further comprises:
combining all the estimates of error associated with the received symbol location from the plurality of N consensus decoders; and
adding the final error estimate to a received symbol value at a particular location.

6. A system comprising:
a processor; and
a computer-readable storage device storing instructions which, when executed by the processor, cause the processor to perform operations comprising:
calculating, via a processor, a syndrome on a received data pattern using a unique subspace parity check matrix inside each of a plurality of N consensus decoders;
generating respective extrinsic information from each check node to variable node in each consensus decoder of the plurality of N consensus decoders to yield complete extrinsic information;
performing a vote on the complete extrinsic information to determine an error estimate for each variable node in each consensus decoder;
combining error estimates for each variable node generated from the plurality of N consensus decoders to yield a final error estimate; and
correcting the received data pattern according to the final error estimate.

7. The system of claim 6, wherein the unique subspace parity check matrix is associated with a generalized Reed-Solomon code.

8. The system of claim 6, wherein performing the vote further comprises performing a unanimous vote.

9. The system of claim 6, wherein performing the vote to determine an error estimate further comprises applying a consensus decoding algorithm to determine the value of a received symbol by applying a first consensus decoder of the plurality of consensus decoders which produces a first estimate of error associated with the received symbol location and a second consensus decoder of the plurality of consensus decoders which produces a second estimate of error associated with the received symbol location, followed by N−2 other consensus decoders each producing an estimate of the error associated with each received symbol location.

10. The system of claim 9, wherein performing the combining of error estimates further comprises:
combining the estimates of error associated with the received symbol location from the plurality of N consensus decoders with the received symbol location to yield the final error estimate; and
adding the final error estimate to a received symbol value at a particular location.

11. A computer-readable storage device storing instructions which, when executed by a computing device, cause the computing device to perform operations comprising:
calculating a syndrome on a received data pattern using a unique subspace parity check matrix inside each of a plurality of consensus decoders;
generating respective extrinsic information from each check node to variable node in each consensus decoder of the plurality of N consensus decoders to yield complete extrinsic information;
performing a vote on the complete extrinsic information to determine an error estimate for each variable node in each consensus decoder;
combining error estimates for each variable node generated from the plurality of N consensus decoders to yield a final error estimate; and
correcting the received data pattern according to the final error estimate.

12. The computer-readable storage device of claim 11, wherein the unique subspace parity check matrix is associated with a generalized Reed-Solomon code.

13. The computer-readable storage device of claim 11, wherein performing the vote further comprises performing a unanimous vote.

14. The computer-readable storage device of claim 1, wherein performing the vote to determine an error estimate further comprises applying a consensus decoding algorithm to determine the value of a received symbol by applying a first consensus decoder of the plurality of consensus decoders which produces a first estimate of error associated with the received symbol location and a second consensus decoder of the plurality of consensus decoders which produces a second estimate of error associated with the received symbol location, followed by N−2 other consensus decoders each producing an estimate of the error associated with each received symbol location.

15. The computer-readable storage device of claim 14, wherein performing the vote to determine an error estimate further comprises:
combining the first estimate of error associated with the received symbol location and the second estimate of error associated with the received symbol location, followed by N−2 other consensus decoders each producing an estimate of the error associated with the received symbol location to yield the final error estimate; and
adding the final error estimate to a received symbol value at a particular location.
